(19) United States
(12) Patent Application Publication
(10) Pub. No.: US 2006/0252266 A1
(43) Pub. Date: Nov. 9, 2006

(54) CMP PROCESS OF HIGH SELECTIVITY

(76) Inventors: Chih-Yueh Lee, Taipei City (TW); Kai-Gin Yang, Tainan County (TW); Chun-Hsien Lin, Tainan Hsien (TW); Yung-Tsung Wei, Tainan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,337

(22) Filed: May 9, 2005

(51) Int. Cl. C03C 15/00; H01L 21/461; B44C 1/22

(52) U.S. Cl. 438/692; 216/88

(57) ABSTRACT

A CMP process of high selectivity is described. A substrate having a first material and a second material thereon is provided. A polishing pad that has multiple first grooves and multiple second grooves crossing the first grooves thereon is provided. The polishing pad and a high-selectivity slurry are then used together to polish the substrate, wherein the high-selectivity slurry has a higher selectivity to the first material than to the second material.

### BACKGROUND OF THE INVENTION

1. Field of the Invention

The present invention relates to a semiconductor process. More particularly, the present invention relates to a chemical mechanical polishing (CMP) process of high selectivity.

2. Description of the Related Art

CMP is a very important technology in modern semiconductor processes. In a typical CMP process, a substrate is pressed onto a rotated polishing pad, while polishing slurry is provided onto the polishing pad so that the surface of the substrate is polished. In the cases where only one or few materials on the substrate surface are to be polished, the selectivity of the polishing slurry to the material(s) is preferably as high as possible to reduce damages of the other material layer(s) on the substrate to a minimum.

Most of high-selectivity slurries (HSS) are chemistry dominated slurries, and are conventionally used in combination with a polishing pad 100 having concentric circular grooves 110 thereon, which is illustrated in FIG. 1. However, HSS generally causes poor uniformity in remaining thickness of the polished layer in the prior art. Though certain methods can be utilized to reduce the non-uniformity (NU) of a CMP process using HSS, more reduced non-uniformity is still required for achieving an even larger process window.

### SUMMARY OF THE INVENTION

In view of the foregoing, this invention provides a CMP process of high selectivity, wherein the polishing pad used has grid-like grooves thereon, rather than concentric circular grooves.

The CMP process of high selectivity of this invention is described as follows. A substrate having a first material and a second material thereon is provided. A polishing pad that has multiple first grooves and multiple second grooves crossing the first grooves thereon is provided. The polishing pad and a polishing slurry are then used together to polish the substrate, wherein the polishing slurry has higher selectivity to the first material than to the second material.

By using the polishing pad with grid-like grooves thereon, the uniformity of polishing the first material with a high-selectivity slurry can be significantly improved, as will be demonstrated by the preferred embodiments of this invention.

It is to be understood that both the foregoing general description and the following detailed description are exemplary, and are intended to provide further explanation of the invention as claimed.

### BRIEF DESCRIPTION OF THE DRAWINGS

FIG. 1 illustrates a polishing pad with concentric circular grooves thereon that is conventionally used in combination with high-selectivity polishing slurry.

FIG. 2 illustrates an XY-groove polishing pad used in a CMP process of high selectivity according to a preferred embodiment of this invention.

FIG. 3 illustrates a portion of another XY-groove polishing pad used in a CMP process of high selectivity according to the preferred embodiment of this invention.

FIG. 4A plots the variation of removal rate (RR, angstrom/min) with the groove density in different regions of the wafer in an exemplary CMP process of this invention, and FIG. 4B plots the variation of non-uniformity (NU %) of CMP with the groove density in the same example.

### DESCRIPTION OF THE PREFERRED EMBODIMENTS

FIG. 2 illustrates a polishing pad 200 having XY-grooves 210 thereon, which is used in a CMP process of high selectivity according to the preferred embodiment of this invention, wherein the surface portions 220 of the polishing pad 200 between the XY-grooves 210 directly contact with the substrate in the CMP process. In such a case, a groove density (GRV %) can be defined as:
GRV %=(X-width of groove/X-pitch of groove)×(Y-width of groove/Y-pitch of groove)
The groove density is generally about 1-30%, preferably about 1-15%, according to the preferred embodiment of this invention.

The selectivity of the high-selectivity slurry used in combination with the pad 200 is preferably about 10 or higher, and the HSS may be one specifically for polishing copper, tungsten or silicon oxide. For example, the CMP process of high selectivity may be a part of a damascene process, which may be a Cu-damascene process wherein a copper layer is formed on an insulator with a trench therein and then a HSS specifically for polishing copper is used to polish the Cu layer to form a conductive line. Analogously, the damascene process may be a W-damascene process wherein a tungsten layer is formed on an insulator with a via hole therein and then a HSS specifically for polishing tungsten is used to polish the tungsten layer to form a conductive plug. In such cases, the higher the selectivity of the polishing slurry to Cu or W than to the insulator, the fewer the damages of the insulator caused by the CMP process. The selectivity is preferably about 10 or higher.

The CMP process of high selectivity of this invention can also be applied to a shallow trench isolation (STI) process. In the STI process, for example, the hard mask material is silicon nitride, the trench-filling material is silicon oxide, and the high-selectivity slurry used has higher selectivity to silicon oxide than to silicon nitride. Similarly, the selectivity is preferably about 10 or higher.

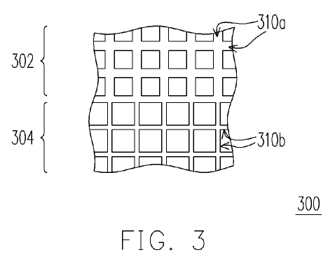

In addition, though the polishing pad 200 illustrated in FIG. 2 has only one groove density, the polishing pad of this invention may alternatively include two or more areas having different groove densities, wherein each groove density is about 1-30% and preferably about 1-15%. FIG. 3 illustrates a portion of such an XY-groove polishing pad 300 that includes two areas 302 and 304, wherein the density of the XY-grooves 310b in the area 304 is lower than that of the XY grooves 310a in the area 302. Use of the area 302 or 304 may be determined according to specific requirements of a CMP process.

In addition, though the X-grooves and the Y-grooves on the polishing pad 200 illustrated in FIG. 2 or in the area 302 or 304 of the polishing pad 300 illustrated in FIG. 3 have the same width, the width of the X-grooves may alternatively be different from that of the Y-grooves to meet certain requirements.

### EXAMPLES

### Example 1

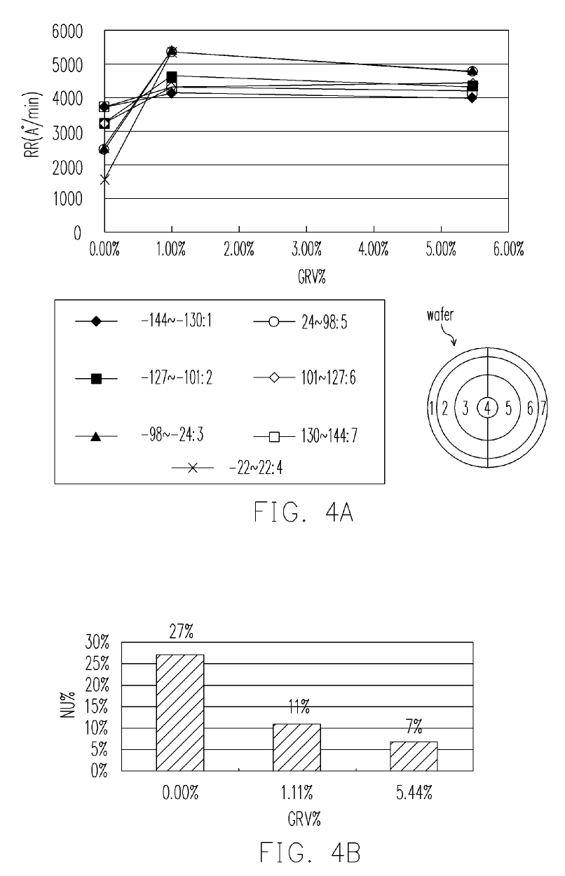

FIG. 4A plots the variation of removal rate (RR, angstrom/min) with the groove density (GRV %) in different regions of a polished wafer in an exemplary CMP process of this invention, wherein the numerical range (e.g., 130-144) corresponding to a region (1, 2, . . . or 7) means a range of distance (mm) from the water center, and the minus sign “−” indicates that the corresponding regions are at the left side of the wafer. FIG. 4B plots the variation of non-uniformity (NU %) of CMP with the groove density in the same example. In this example, a copper layer formed on an insulator with a trench therein is polished, wherein the selectivity of the polishing slurry to copper is about 100 relative to its selectivity to the insulator.

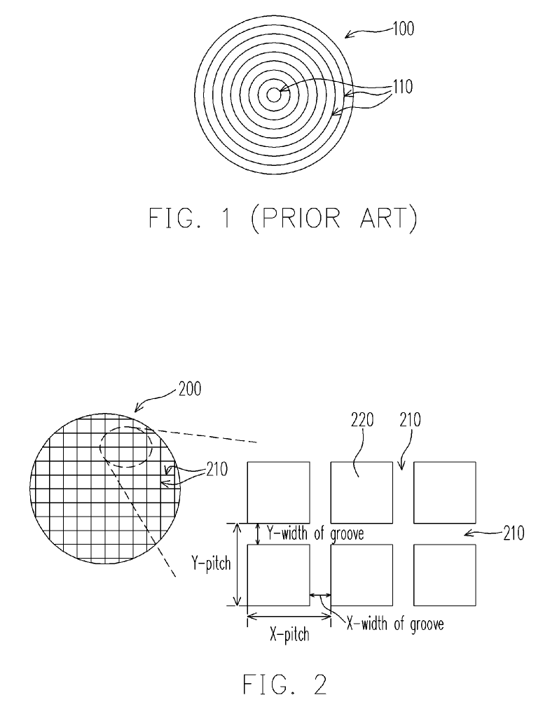

As shown in FIG. 4, when the groove density is increased, the differences between the removal rates in different regions of the wafer are smaller, which means smaller non-uniformity of the CMP process, as shown in FIG. 4B. The result of using the polishing pad 100 illustrated in FIG. 1 is even worse as compared with the case of GRV %=0%, in which a smooth polishing pad without any groove thereon is used.

### Example 2

In this example, a silicon oxide layer formed as a trench-filling material of a STI process is polished to form an STI structure, while a patterned silicon nitride layer as a hard mask and shallow trenches have been formed on the wafers previously. The selectivity of the high-selectivity slurry to silicon oxide is about 30 relative to its selectivity to silicon nitride. A polishing pad of GRV %>5% and another polishing pad of GRV %=0 are used respectively to show the NU-reduction effect of this invention. In addition, two different polishing heads are used respectively to prove that the NU-reduction effect is not caused by the polishing head.

After the CMP process, RR and NU % are estimated through diameter scan of the thickness of the remaining silicon oxide layers (labeled with “Line” in Table 1) and through polar mapping of the thickness (labeled with “Polar”), respectively, to prove that the NU-reduction effect is not caused by the estimating method of RR and NU %. In the former estimating method, the thickness of the remaining oxide layer is measured along some lines passing the center of the wafer; while in the later method, the polar map of thickness of the remaining oxide layer is made for estimating RR and NU %. The results are shown in Table. 1

TABLE 1

| GRV % > 5% | | Head 1 | Head 2 | GRV % = 0 | | Head 1 | Head 2 |
|---|---|---|---|---|---|---|---|
| Line | RR | 3564.3 | 3591.5 | Line | RR | 3191.0 | 3178.0 |
| | NU % | 2.4 | 2.7 | | NU % | 4.6 | 4.8 |
| Polar | RR | 3232.5 | 3468.3 | Polar | RR | 3276.0 | 3287.0 |
| | NU % | 4.5 | 4.2 | | NU % | 7.5 | 8.2 |

According to the results shown in Table 1, when RR and NU % are estimated through diameter scan of thickness (Line), the removal rates of using the pad of GRV %=0 are found to be lower than those of using the pad of GRV %>5%. When the estimation is made through polar mapping of thickness, the removal rates of using the former are found to be approximately the same as those of using the latter. However, no matter how the non-uniformity of the oxide layers estimated, the polishing pad of GRV %>5% makes much smaller non-uniformity as compared with the flat polishing pad of GRV %=0.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1-12. (canceled)

13. A chemical mechanical polishing (CMP) process of high selectivity, comprising:
providing a substrate having at least a first material and a second material thereon;
providing a polishing pad, which has a plurality of first grooves and a plurality of second grooves substantially perpendicularly crossing the first grooves thereon, wherein the polishing pad has a groove density of about 1%-30%; and
using the polishing pad and a high-selectivity slurry to polish the substrate, wherein the high-selectivity slurry has a selectivity of about 10 or more to the first material relative to the selectivity the second material.

14. The CMP process of claim 13, wherein the groove density is about 1%-15%.

15. The CMP process of claim 13, wherein the polishing pad includes at least two areas having different groove densities, wherein each groove density is about 1%-30%.

16. The CMP process of claim 15, wherein each groove density is about 1%-15%.

17. The CMP process of claim 13, wherein the first material comprises copper, tungsten or silicon oxide.

18. The CMP process of claim 17, wherein the first material comprises copper or tungsten, and the second material comprises an insulator.

19. The CMP process of claim 17, wherein the first material comprises silicon oxide as a trench-filling material in an STI process, and the second material comprises silicon nitride as a hard mask material in the STI process.

20. The CMP process of claim 13, wherein the polishing pad comprises rubber.
